(19) United States
(12) Patent Application Publication
(10) Pub. No.: US 2023/0055987 A1
(43) Pub. Date: Feb. 23, 2023

(54) PLANAR COIL, AND DEVICE FOR MANUFACTURING SEMICONDUCTOR COMPRISING SAME

(71) Applicant: KYOCERA Corporation, Kyoto-shi, Kyoto (JP)

(72) Inventor: Takeshi MUNEISHI, Kusatsu-shi, Shiga, Japan (JP)

(21) Appl. No.: 17/795,365

(22) PCT Filed: Jan. 28, 2021
(86) PCT No.: PCT/JP2021/003116

§ 371 Date: Jul. 26, 2022

(30) Foreign Application Priority Data
Jan. 28, 2020 (JP) 2020-011717

(51) Int. Cl. H01F 27/28; H01F 38/14; H01F 41/04

(52) U.S. Cl. CPC H01F 27/288; H01F 38/14; H01F 27/2804; H01F 41/041

(57) ABSTRACT

A planar coil (10) of the present disclosure includes a base (1) including a first surface (1a), a metal layer (2) located on the first surface (1a) and including a through hole (2a) and a plurality of voids (3), and a first fixing tool (8) inserted through the through hole (2a) and fixing the metal layer (2) to the first surface (1a) side of the base (1).

### TECHNICAL FIELD

The present disclosure relates to a planar coil and a semiconductor manufacturing device provided with the same.

### BACKGROUND ART

A planar coil is used in a semiconductor manufacturing device. For example, Patent Document 1 describes that high-frequency electrical power from 10 MHz to 500 MHz is supplied to a coil in order to generate plasma for processing a wafer to be a semiconductor.

### CITATION LIST

### Patent Literature

Patent Document 1: JP 2015-95521 A

### SUMMARY OF INVENTION

A planar coil of the present disclosure includes a base including a first surface, a metal layer located on the first surface and including a through hole and a plurality of voids, and a first fixing tool inserted through the through hole and fixing the metal layer to the first surface side of the base.

### BRIEF DESCRIPTION OF DRAWINGS

FIG. 1 is a plan view of an example of a planar coil of the present disclosure when viewed from a first surface side.

FIG. 2 is a diagram illustrating an example of an enlarged view in an S portion illustrated in FIG. 1.

FIG. 3 is a diagram illustrating an example of an enlarged view in the S portion illustrated in FIG. 1.

FIG. 4 is a diagram illustrating an example of an enlarged view in the S portion illustrated in FIG. 1.

FIG. 5 is a diagram illustrating an example of an enlarged view in the S portion illustrated in FIG. 1.

FIG. 6 is a diagram illustrating an example of a cross-sectional view taken along line A-A′ in FIG. 1.

FIG. 7 is a diagram illustrating another example of a cross-sectional view taken along line A-A′ in FIG. 1.

FIG. 8 is a partial cross-sectional view of another example of the planar coil of the present disclosure.

FIG. 9 is a partial cross-sectional view of another example of the planar coil of the present disclosure.

FIG. 10 is a partial cross-sectional view of another example of the planar coil of the present disclosure.

FIG. 11 is a partial cross-sectional view of another example of the planar coil of the present disclosure.

FIG. 12 is a cross-sectional view of a semiconductor manufacturing device according to the present disclosure.

FIG. 13 is a view of an example of a manufacturing method for the planar coil of the present disclosure.

### DESCRIPTION OF EMBODIMENTS

A planar coil of the present disclosure and a semiconductor manufacturing device provided with the same will be described in detail below with reference to the drawings.

A planar coil is used in a semiconductor manufacturing device. For example, a technique is disclosed in which high-frequency electrical power from 10 MHz to 500 MHz is supplied to a coil in order to generate plasma for processing a wafer to be a semiconductor.

On the other hand, when high-frequency electrical power is supplied to the coil, the coil generates heat and thermally expands accordingly, so that the coil is not stably held on the base.

Thus, a technique to overcome the aforementioned problem and improve reliability of the planar coil awaits realization.

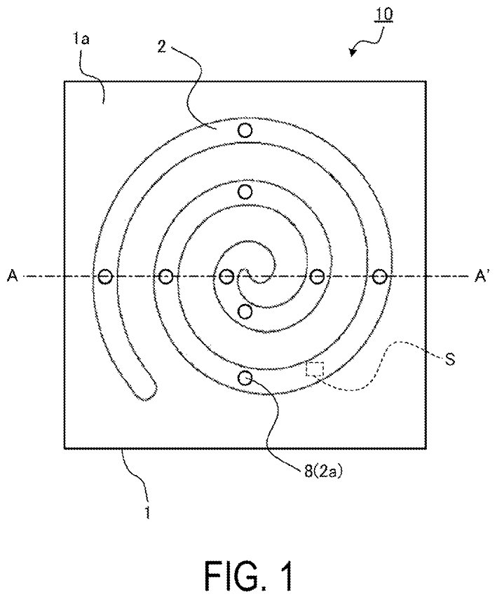

As illustrated in FIG. 1 and FIG. 6, a planar coil 10 of the present disclosure includes a base 1 including a first surface 1a. Furthermore, the planar coil 10 includes a metal layer 2 located on the first surface 1a.

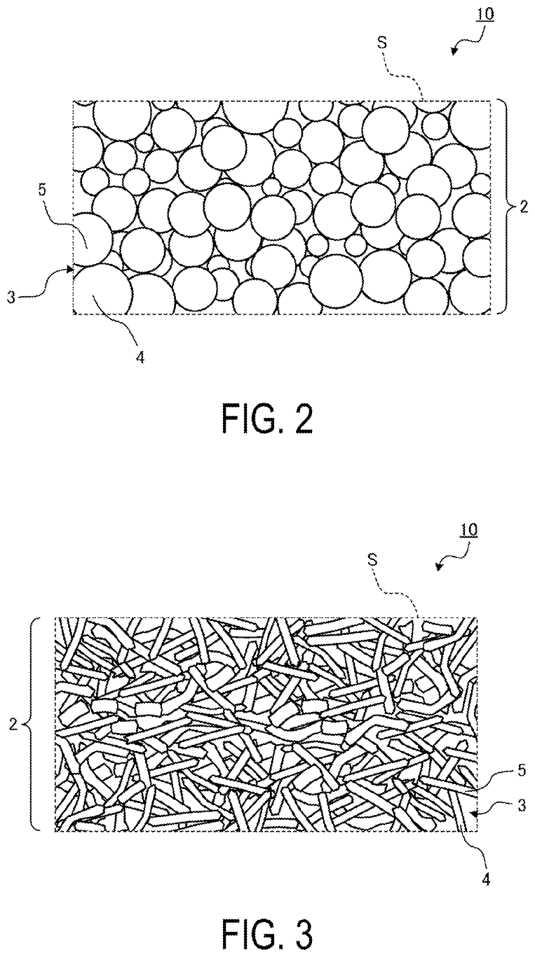

As illustrated in FIGS. 2 to 5, the metal layer 2 includes a plurality of voids 3. Thus, the surface area of the metal layer 2 is larger than that of a metal layer including no voids. Consequently, the planar coil 10 has high heat dissipation.

Then, as illustrated in FIGS. 1 and 6, the metal layer 2 includes through holes 2a. The planar coil 10 includes first fixing tools 8 inserted through the through holes 2a. The first fixing tools 8 are fixed to the first surface 1a side of the base 1, thus fixing the metal layer 2 to the first surface 1a side of the base 1. As a result, the metal layer 2 is stably held on the base 1. Consequently, the planar coil 10 has high reliability.

Furthermore, as illustrated in FIGS. 2 and 3, the metal layer 2 may include first metal particles 4 and second metal particles 5. The voids 3 may be located between the first metal particles 4 and the second metal particles 5. With such a configuration, heat generated by the first metal particles 4 and the second metal particles 5 is absorbed by the voids 3, so that the planar coil 10 has high heat dissipation.

Materials of the first metal particles 4 and the second metal particles 5 constituting the metal layer 2 may be, for example, stainless steel or copper.

As illustrated in FIG. 2 and FIG. 3, the first metal particles 4 and the second metal particles 5 may each have a spherical shape, a granular shape, a whisker shape, or a needle shape, for example. When the first metal particles 4 and the second metal particles 5 each have a whisker shape or a needle shape, the first metal particles 4 and the second metal particles 5 may be bent. The first metal particles 4 and the second metal particles 5 may each include corners.

When the first metal particles 4 and the second metal particles 5 each have a spherical shape or a granular shape, the longitudinal lengths of the first metal particles 4 and the second metal particles 5 may be 0.5 μm or more and 200 μm or less. When the first metal particles 4 and the second metal particles 5 each have a whisker shape or a needle shape, the diameter may be 1 μm or more and 100 μm or less, and the length may be 100 μm or more and 5 mm or less.

In FIG. 2. the first metal particles 4 and the second metal particles 5 each have a granular shape. In FIG. 3, the first metal particles 4 and the second metal particles 5 each have a whisker shape.

Furthermore, the average thickness of the metal layer 2 may be 1 μm or more and 5 mm or less.

Furthermore, the size of each of the through holes 2a may be 1 mm or more and 15 mm or less in diameter when viewed in a plan view in parallel with the first surface 1a of the base 1.

Furthermore, the porosity of the metal layer 2 may be, for example, 10% or more and 90% or less. The porosity is an index representing a percentage of the voids 3 in the metal layer 2, and the porosity of the metal layer 2 may be calculated by measurement using the Archimedes method.

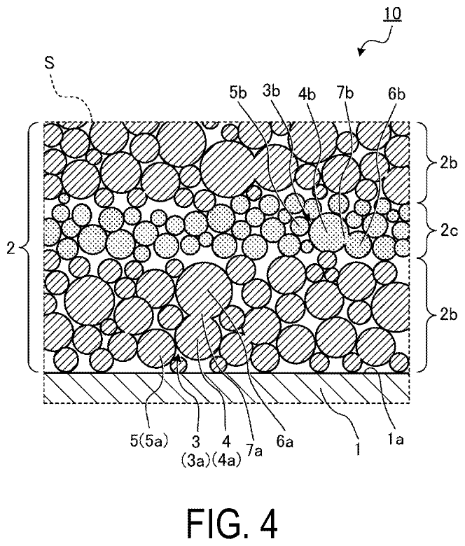

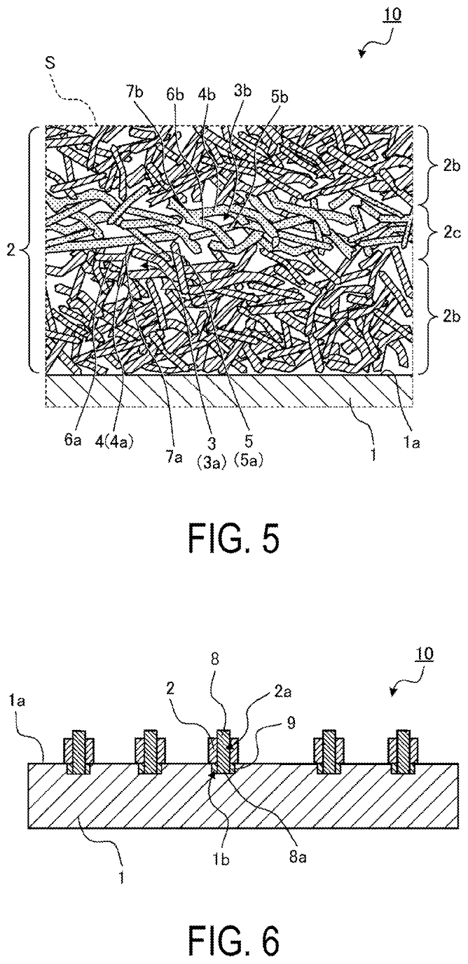

Furthermore, as illustrated in FIGS. 4 and 5, the metal layer 2 may be configured by layering a plurality of thin film coil conductors 2b via a shielding layer 2c on the first surface 1a in the thickness direction of the plurality of thin film coil conductors 2b to form a multilayer structure. Thus, even when high-frequency electrical power is applied to the metal layer 2, interference between the thin film coil conductors 2b adjacent to each other can be suppressed by the shielding layer 2c.

Note that in the examples illustrated in FIGS. 4 and 5, structures are illustrated in which the thin film coil conductor 2b is located closest to the base 1 side, but a structure in which the shielding layer 2c is located closest to the base 1 side may be used.

In the planar coil 10 of the present disclosure, the thin film coil conductors 2b include voids 3a. Thus, the thin film coil conductors 2b have a larger surface area than that of a thin film coil conductor including no voids. Consequently, the planar coil 10 has high heat dissipation.

Furthermore, as illustrated in FIGS. 4 and 5, the thin film coil conductors 2b may include first metal particles 4a and second metal particles 5a. The voids 3a may be located between the first metal particles 4a and the second metal particles 5a. With such a configuration, heat generated by the first metal particles 4a and the second metal particles 5a is absorbed by the voids 3a, so that the planar coil 10 has high heat dissipation.

Materials of the first metal particles 4a and the second metal particles 5a constituting the thin film coil conductors 2b may be, for example, stainless steel or copper.

As illustrated in FIGS. 4 and 5, the shape of the first metal particles 4a and the second metal particles 5a may be spherical, granular, whisker shape, or needle shape, for example. In a case where the first metal particles 4a and the second metal particles 5a are whisker shape or needle shape, the first metal particles 4a and the second metal particles 5a may be bent. The first metal particles 4a and the second metal particles 5a may include corner portions.

In a case where the first metal particles 4a and the second metal particles 5a are spherical or granular, the longitudinal length of the first metal particles 4a and the second metal particles 5a may range from 0.5 μm to 200 μm. When the first metal particles 4a and the second metal particles 5a each have a whisker shape or a needle shape, the diameter may be 1 μm or more and 100 μm or less, and the length may be 100 μm or more and 5 mm or less.

In FIG. 4, the first metal particles 4a and the second metal particles 5a are granular. In FIG. 5, the first metal particles 4a and the second metal particles 5a are whisker shape.

Furthermore, the porosity of the thin film coil conductors 2b may be, for example, 10% or more and 90% or less. The porosity is an index representing a percentage of the voids 3a in the thin film coil conductors 2b. Here, the porosity of the thin film coil conductors 2b may be calculated by performing measurement using the Archimedes method, for example.

Furthermore, as illustrated in FIGS. 4 and 5, the thin film coil conductors 2b may include third metal particles 6a. The thin film coil conductors 2b may include welded parts 7a between the first metal particles 4a and the third metal particles 6a.

Since the first metal particles 4a and the third metal particles 6a are welded together rather than just being simply in contact with one another, the first metal particles 4a and the third metal particles 6a easily transfer heat between one another. Thus, the entirety of the thin film coil conductors 2b has high thermal conductivity. Consequently, the planar coil 10 has high reliability.

In the planar coil 10 of the present disclosure, the thin film coil conductors 2b may have a larger thickness than that of the shielding layer 2c. With such a configuration, the region of the thin film coil conductors 2b increases in the interior of the metal layer 2, and thus electrical efficiency is improved.

Here, the thickness of each of the thin film coil conductors 2b may be from 10 μm to 300 μm, and the thickness of the shielding layer 2c may be from 0.1 μm to 500 μm. The thickness of the metal layer 2 may be from 0.5 mm to 5 mm, and the thin film coil conductors 2b and the shielding layer 2c can be layered within the range of this thickness.

Furthermore, as illustrated in FIGS. 4 and 5, the shielding layer 2c may include first shielding particles 4b and second shielding particles 5b. Voids 3b may be located between the first shielding particles 4a and the second shielding particles 5b. With such a configuration, heat generated by the thin film coil conductors 2b is transferred through the first shielding particles 4b and the second shielding particles 5b and absorbed in the voids 3b, so that the planar coil 10 has high heat dissipation.

Here, materials of the first shielding particles 4b and the second shielding particles 5b constituting the shielding layer 2c are, for example, an insulating material or a material more magnetic than the thin film coil conductors 2b. Examples of the insulating material are a ceramic, such as aluminum oxide, zirconium oxide, or silicon carbide, a resin such as a polyimide, polyamide, polyimideamide, silicone, epoxy, or fluorine-based resin, and a glass such as borosilicate glass or silicate glass.

Furthermore, a material more magnetic than the thin film coil conductors 2b is, for example, nickel or iron in a case where the thin film coil conductors 2b are stainless steel or copper. Note that the insulating material and the magnetic material may be mixed, and, for example, a nickel powder or an iron powder may be mixed with a polyimide resin.

As illustrated in FIGS. 4 and 5, the shape of the first shielding particles 4b and the second shielding particles 5b may be spherical, granular, whisker shape, or needle shape, for example. In a case where the first shielding particles 4b and the second shielding particles 5b are whisker shape or needle shape, the first shielding particles 4b and the second shielding particles 5b may be bent. The first shielding particles 4b and the second shielding particles 5b may include corner portions.

In a case where the first shielding particles 4b and the second shielding particles 5b are spherical or granular, the longitudinal length of the first shielding particles 4b and the second shielding particles 5b may range from 0.5 μm to 200 μm. When the first shielding particles 4b and the second shielding particles 5b each have a whisker shape or a needle shape, the diameter may be 1 μm or more and 100 μm or less, and the length may be 100 μm or more and 5 μm or less.

In FIG. 4, the first shielding particles 4b and the second shielding particles 5b are granular. In FIG. 5, the first shielding particles 4b and the second shielding particles 5b are whisker shape.

Furthermore, the porosity of the shielding layer 2c may be, for example, 10% or more and 90% or less. The porosity is an index representing a percentage of the voids 3b in the thin shielding layer 2c. Here, the porosity of the shielding layer 2c may be calculated by performing measurement using the Archimedes method, for example.

As illustrated in FIGS. 4 and 5, the shielding layer 2c may include third shielding particles 6b. The shielding layer 2c may include a welded part 7b between the first shielding particles 4b and the third shielding particles 6b.

Since the first shielding particles 4b and the third shielding particles 6b are welded together rather than just being simply in contact with one another, the first shielding particles 4b and the third shielding particles 6b easily transfer heat between one another. Thus, the entirety of the shielding layer 2c has high thermal conductivity. Consequently, the planar coil 10 has high reliability.

As illustrated in FIG. 1, the base 1 may have a plate shape. Furthermore, the metal layer 2 may be located on the first surface 1a of the base 1 in a meandering shape or a spiral shape. Furthermore, the metal layer 2 may be positioned on the first surface 1a of the base 1 in any arrangement.

Furthermore, the base 1 in the planar coil 10 of the present disclosure may be a ceramic. Examples of the ceramic include an aluminum oxide ceramic (sapphire), a silicon carbide ceramic, a cordierite ceramic, a silicon nitride ceramic, an aluminum nitride ceramic, a mullite ceramic, and the like.

When the base 1 is made of an aluminum oxide ceramic, it is easy to process and inexpensive. Here, for example, an aluminum oxide ceramic is a material in which aluminum oxide accounts for 70 mass % or more among 100 mass % as all the components which constitute the ceramic. The material of the base 1 in the planar coil 10 of the present disclosure may be confirmed by the following method.

First, from the value of 2θ (2θ indicates a diffraction angle) obtained from measurement of the base 1 by using an X-ray diffractometer (XRD), identification is performed by using a JCPDS card. Next, a quantitative analysis of contained components is performed using an X-ray fluorescent (XRF) analyzer.

Then, if the presence of aluminum oxide is confirmed by the above-described identification and the content converted from the content of aluminum (Al) measured by XRF to aluminum oxide (Al₂O₃) is 70 mass % or greater, the material is an aluminum oxide ceramic. Note that other ceramics can also be confirmed by the same method.

Furthermore, the base 1 in the planar coil 10 of the present disclosure may be a magnetic material.

The magnetic material has magnetism, or has magnetism imparted by an external magnetic field. Examples of the magnetic material include ferrite, iron, silicon iron, iron-nickel based alloys, and iron-cobalt based alloys. Permalloy is an example of an iron-nickel based alloy. Furthermore, permendur is an example of an iron-cobalt based alloy. When the base 1 is a magnetic material, it may be used as a magnetic core (core).

As illustrated in FIG. 6, in the planar coil 10 of the present disclosure, the metal layer 2 may include a plurality of the through holes 2a and may include a plurality of the first fixing tools 8 disposed in the plurality of through holes 2a, respectively. With such a configuration, the metal layer 2 is more stably held, and thus reliability can be enhanced.

As illustrated in FIG. 6, in the planar coil 10 of the present disclosure, recessed portions 1b may be provided on the first surface 1a of the base 1, and one end portion 8a of each of the first fixing tools 8 may be provided in a corresponding one of the recessed portions 1b. With such a configuration, the first fixing tools 8 are stable, and thus reliability can be enhanced. Note that one end portion 8a of each of the first fixing tools 8 may be fixed in the corresponding one of the recessed portions 1b by fitting or screwing.

The planar coil 10 of the present disclosure may include an adhesive layer 9 in each of the recessed portions 1b as illustrated in FIG. 6. With such a configuration, the first fixing tools 8 are more stable, and thus reliability can be enhanced. Examples of the material of the adhesive layer 9 include an organic adhesive or an inorganic adhesive, and the organic adhesive is a silicone-based adhesive, an imideamide-based adhesive, an epoxy-based adhesive, or the like and the inorganic adhesive is a glass-based adhesive, a metal wax-based adhesive, or the like.

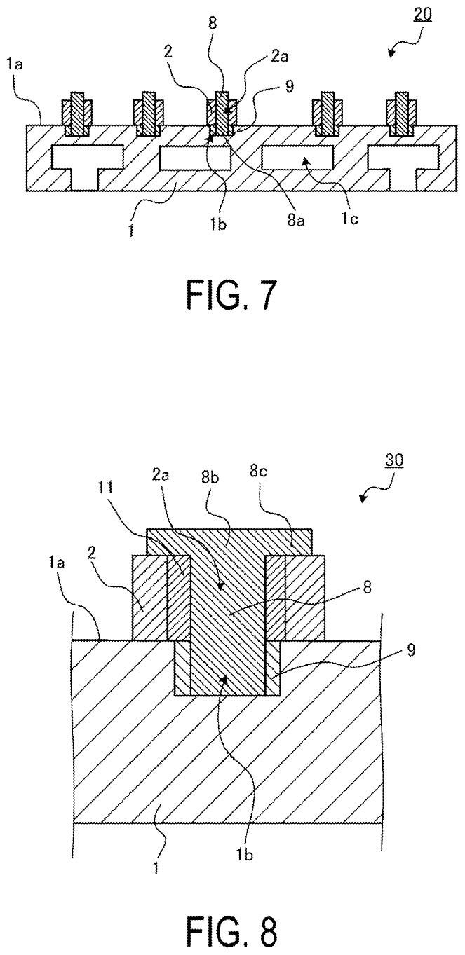

FIG. 7 is a diagram illustrating another example of a cross-sectional view taken along line A-A′ in FIG. 1. As illustrated in FIG. 7, in a planar coil 20 of the present disclosure, the base 1 may include a channel 1c therein. With such a configuration, when a temperature control medium flows through the channels 1c, the planar coil 20 can be cooled, and thus reliability can be enhanced. In addition, a process gas when manufacturing the semiconductor, rather than the temperature control medium, may flow through the channels 1c.

FIG. 8 is a partial cross-sectional view of another example of the planar coil of the present disclosure. A planar coil 30 of the present disclosure may include a protective layer 11 between the first fixing tool 8 and the metal layer 2, as illustrated in FIG. 8. With such a configuration, even when the metal layer 2 repeatedly expands due to heat generation and contracts due to cooling, the metal layer 2 does not abut against the first fixing tool 8 and is not damaged, and thus reliability can be enhanced.

In the planar coil 30 of the present disclosure the protective layer 11 may be an insulating material. With such a configuration, electricity does not flow through the first fixing tool 8, and electric field concentration is less likely to occur, and thus reliability can be enhanced.

Furthermore, in the planar coil 30 of the present disclosure, the protective layer 11 may be a resin. With such a configuration, the metal layer 2 is not damaged by the protective layer 11, and thus reliability can be enhanced. Examples of the material of the protective layer 11 may be a silicone-based resin, an imidoamide resin, a fluorine-based resin, or the like.

The planar coil 30 of the present disclosure may include a flange 8c on the other end portion 8b of the first fixing tool 8. With such a configuration, the flange 8c sandwiches the metal layer 2 or the protective layer 11 with the base 1, and the metal layer 2 or the protective layer 11 can be more stably held, and thus reliability can be enhanced.

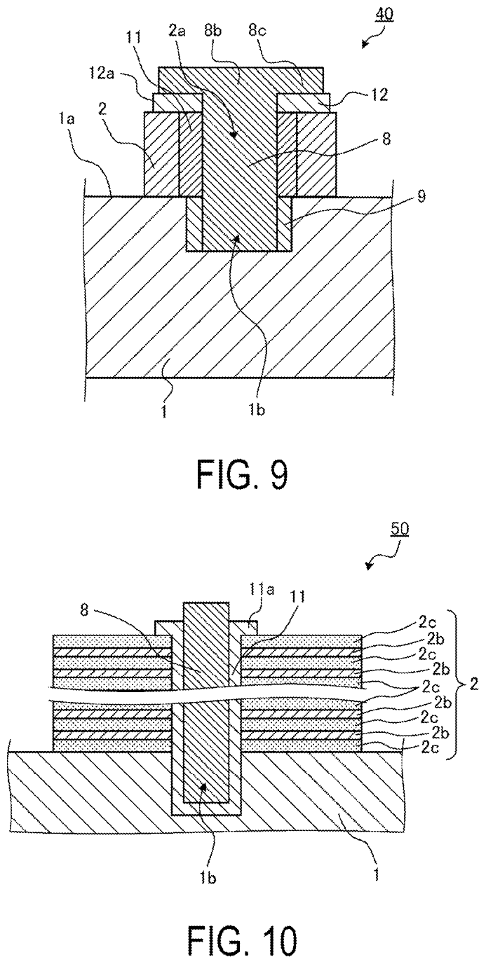

FIG. 9 is a partial cross-sectional view of another example of the planar coil of the present disclosure. In a planar coil 40 of the present disclosure, a second fixing tool 12 is located between the flange 8c of the first fixing tool 8 and the metal layer 2 or the protective layer 11, and an outer periphery 12a of the second fixing tool 12 is outside the flange 8c of the first fixing tool 8. With such a configuration, the metal layer 2 or the protective layer 11 can be more stably held also by the second fixing tool 12, and thus reliability can be enhanced.

In the planar coil 40 of the present disclosure the second fixing tool 12 may be an insulating material. With such a configuration, since electricity does not flow through the second fixing tool 12 or through the first fixing tool 8, abnormal heating does not occur, and thus heat dissipation can be enhanced.

Examples of the material of the second fixing tool 12 may be a glass, resin, ceramic, or the like. The resin may be a silicone resin, an imideamide resin, or a fluororesin, and the ceramic may be an aluminum oxide ceramic (sapphire), a silicon carbide ceramic, a cordierite ceramic, a silicon nitride ceramic, an aluminum a nitride ceramic, or a mullite ceramic.

In the planar coil 40 of the present disclosure the first fixing tool 8 may be a ceramic that is an insulating material. With such a configuration, the mechanical strength of the first fixing tool 8 is large and electricity does not flow, and thus electric field concentration is less likely to occur, and reliability can be enhanced.

FIG. 10 is a partial cross-sectional view of another example of the planar coil of the present disclosure. In a planar coil 50 illustrated in FIG. 10, a metal layer 2 is used in which the thin film coil conductors 2b and the shielding layers 2c illustrated in FIGS. 4 and 5 are alternately layered on one another.

The planar coil 50 illustrated in FIG. 10 may include the protective layer 11 between the first fixing tool 8 and the metal layer 2, similarly to the planar coils 30 and 40 described above. With such a configuration, even when the metal layer 2 minutely vibrates due to high-frequency electrical power supply, the metal layer 2 does not abut against the first fixing tool 8 and is not damaged, and thus reliability can be enhanced.

In the planar coil 50 of the present disclosure the protective layer 11 may be a material (for example, resin) softer than the thin film coil conductors 2b. With such a configuration, the thin film coil conductor 2b of the metal layer 2 is not damaged by friction with the protective layer 11, and thus reliability can be enhanced. Examples of the material of the protective layer 11 may be a silicone-based resin, an imidoamide resin, a fluorine-based resin, or the like.

Furthermore, as illustrated in FIG. 10, in the planar coil 50 of the present disclosure, the shielding layer 2c may be disposed at the lowermost layer (i.e., the interface with the base 1) of the metal layer 2. With such a configuration, even when the metal layer 2 minutely vibrates due to high-frequency electrical power supply, the thin film coil conductors 2b do not abut against the base 1 and are not damaged, and thus reliability can be enhanced.

In the planar coil 50 of the present disclosure the shielding layers 2c may be a material (for example, resin) softer than the thin film coil conductors 2b. With such a configuration, the minute vibration of the thin film coil conductors 2b can be absorbed by the shielding layers 2c, and the thin film coil conductors 2b of the metal layer 2 are not damaged by friction with the base 1, and thus reliability can be enhanced.

Examples of the material of the shielding layers 2c are an insulating material or a material more magnetic than the thin film coil conductors 2b. Examples of the insulating material may be a ceramic such as aluminum oxide, zirconium oxide, or silicon carbide, a resin such as a polyimide, polyamide, polyimideamide, silicone, epoxy, or fluorine-based resin, and a glass such as borosilicate glass or silicate glass. The material of the shielding layers 2c may be the same as or different from the material of the protective layer 11.

Furthermore, a material more magnetic than the thin film coil conductors 2b is, for example, nickel or iron in a case where the thin film coil conductors 2b are stainless steel or copper.

In the example in FIG. 10, the material of the shielding layers 2c may be the insulating material or the material more magnetic than the thin film coil conductors 2b, or may be a mixture of the insulating material or the material more magnetic than the thin film coil conductors 2b and the resin. For example, the nickel powder or the iron powder may be mixed with the polyimide resin.

As described above, the shielding layers 2c are made of a mixture of the insulating material or the material more magnetic than the thin film coil conductors 2b and the resin, and thus both a shielding effect and flexibility can be achieved.

Furthermore, in the planar coil 50 of the present disclosure, the shielding layer 2c may be disposed at the uppermost layer of the metal layer 2. With such a configuration, even when foreign matter or the like is attached to the metal layer 2, the foreign matter does not abut against the thin film coil conductors 2b and the thin film coil conductors 2b are not damaged, and thus reliability can be enhanced.

Furthermore, in the planar coil 50 of the present disclosure, the shielding layer 2c may be thicker than the thin film coil conductor 2b. With such a configuration, minute vibration of the thin film coil conductors 2b in the metal layer 2 by the high-frequency electrical power supply can be suppressed by the thick shielding layers 2c.

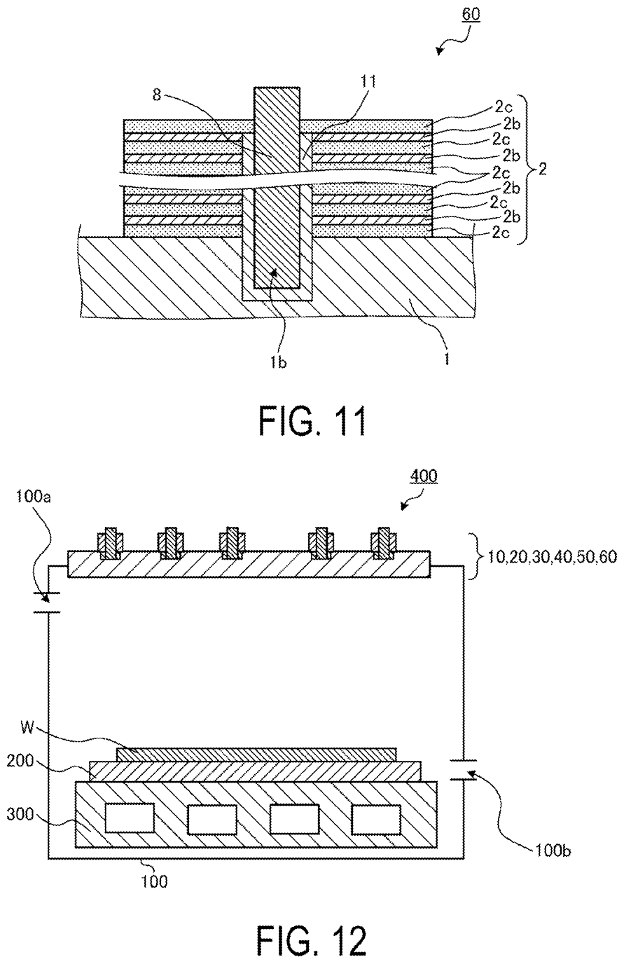

Furthermore, the planar coil 50 of the present disclosure may include a flange 11a on an end portion of the protective layer 11 exposed from the uppermost layer of the metal layer 2. With such a configuration, the flange 11a sandwiches the metal layer 2 with the base 1, and the metal layer 2 can be more stably held, and thus reliability can be enhanced. Note that, as illustrated in FIG. 11, the protective layer 11 need not include the flange 11a.

FIG. 12 is a cross-sectional view of a semiconductor manufacturing device according to the present disclosure. An electrostatic chuck 200 and a cooling member 300 are provided in a chamber 100. The cooling member 300 is a conductor or coated with a conductor and thus the cooling member 300 can be used as a lower electrode of a high-frequency electrode. Furthermore, a wafer W is fixed to the electrostatic chuck 200.

The chamber 100 includes a gas inflow opening 100a in which a process gas enters the chamber 100, and a gas outflow opening 100b in which the process gas flows out from the chamber 100.

The chamber 100 is provided with the planar coil 10, but the semiconductor manufacturing device 400 of the present disclosure may use the planar coils 10, 20, 30, 40, 50, and 60 as an antenna for high-frequency electrical power. With such a configuration, the planar coils 10, 20, 30, 40, 50, and 60 have high heat dissipation and have high reliability, and thus, when plasma treatment is performed with the antenna for high-frequency electrical power as the upper electrode, the semiconductor can be stably manufactured.

Next, an example of a method for manufacturing the planar coil of the present disclosure will be described.

First, the base 1 is prepared. The base 1 may include the channels 1c. Furthermore, the base 1 may include the recessed portions 1b.

Next, the metal layer 2 is separately prepared. First, for example, a liquid mixture in which a plurality of metal particles made of stainless steel or copper are mixed with a liquid such as water is prepared, and is poured into a mold having a shape of the metal layer 2. Next, the liquid mixture is evaporated. Next, the first metal particles 4 and the second metal particles 5 are bonded through application of a predetermined pressure and heating or by ultrasonic vibration. Then, when taken out from the mold, the first metal particles 4 and second metal particles 5 have been bonded to obtain the metal layer 2 including the voids 3.

Furthermore, the metal layer 2 may be made by the following method. First, after a plurality of metal particles including the first metal particles 4 and the second metal particles 5 are mixed with a binder, a molded body is produced by a mechanical pressing method. Next, the binder is evaporated by drying the molded body. Then, it is heated or ultrasonically vibrated. This allows the first metal particles 4 and the second metal particles 5 to be bonded to acquire the metal layer 2 including the voids 3.

Furthermore, the metal layer 2 may be made by the following method. First, after a plurality of metal particles including the first metal particles 4a and the second metal particles 5a are mixed with a binder, a molded body is produced by a mechanical pressing method. Alternatively, a slurry in which a plurality of metal particles including the first metal particles 4a and the second metal particles 5a are mixed with a binder is prepared, and a molded body is produced by a papermaking method.

The compact is then dried to evaporate the binder. Thereafter, heat, ultrasonic vibration, or electricity is applied. In this manner, the plurality of metal particles including the first metal particles 4a and the second metal particles 5a can be welded together. In this manner, the welded parts 7a can be formed between the first metal particles 4a and the third metal particles 6a. Accordingly, the thin film coil conductor 2b with voids 3a is obtained.

Next, the shielding layer 2c is prepared. The shielding layer 2c is made of the insulating material or the material more magnetic than the thin film coil conductor 2b, but may be made by the same method as that of the thin film coil conductor 2b. When there is no need to include the voids 3b, a dense body may be used, and in this case a method such as an extrusion method or an injection molding method can be used.

Next, the plurality of thin film coil conductors 2b and the shielding layers 2c are alternately layered on one another and subsequently pressed, and thus the metal layer 2 in which the thin film coil conductors 2b and the shielding layers 2c are layered can be obtained.

Note that the shielding layers 2c can be formed by electroless plating. After layering only the plurality of thin film coil conductors 2b, electroless plating of nickel using platinum as a catalyst is performed. Platinum and nickel enter gaps between the thin film coil conductors 2b, and thus the shielding layers 2c are formed. By using such a forming method of the shielding layers 2c, the shielding layers 2c thinner than the thin film coil conductors 2b can be formed.

Next, the through holes 2a are formed in the obtained metal layer 2 by machining, blasting, or the like. Note that the through holes 2a may be formed in the manufacturing process of the molded body of the metal layer 2.

Next, the metal layer 2 is placed on the base 1. The planar coil 10 can be obtained by passing the first fixing tools 8 through the through holes 2a of the metal layer 2.

Note that when the base 1 includes the recessed portions 1b, one end portion 8a of each of the first fixing tools 8 may be fixed in a corresponding one of the recessed portions 1b by fitting or screwing, or the adhesive layer 9 may be formed by injecting an organic or inorganic adhesive in the recessed portions 1b in advance and thereafter inserting the one end portion 8a of each of the first fixing tools 8.

Furthermore, after a member to be the protective layer 11 has been inserted in the through holes 2a of the metal layer 2 in advance, fixing with the first fixing tools 8 may be performed. The other end 8b of each of the first fixing tools 8 may include the flange 8c, or the second fixing tools 12 may be used.

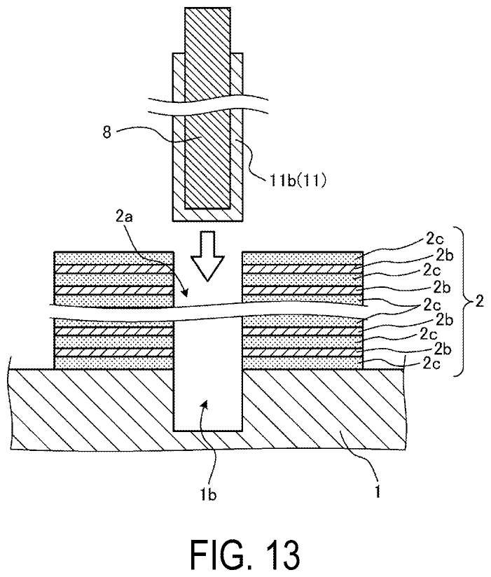

Furthermore, for the planar coils 50 and 60 illustrated in FIGS. 10 and 11, as illustrated in FIG. 13, a resin paste 11b to be the protective layer 11 is applied to the bottom side of each of the first fixing tools 8 and the first fixing tools 8 coated with the resin paste 11b may be inserted into a corresponding one of the through holes 2a and the recessed portions 1b. The resin paste 11b may then be cured, and formed as the protective layer 11 that fixes the metal layer 2 and the first fixing tool 8 to each other.

When such a manufacturing method is used, the resin paste 11b enters some of the voids of the thin film coil conductors 2b and the shielding layers 2c of the metal layer 2, and thus the metal layer 2 and the first fixing tool 8 can be more firmly fixed to each other.

Note that the present disclosure is not limited to the above-described embodiment, and various modifications, enhancements, and the like may be made without departing from the scope of the present disclosure.

### REFERENCE SIGNS LIST

1 Base
2 Metal layer
2a Through hole
2b Thin film coil conductor
2c Shielding layer
3, 3a Voids
4, 4a First metal particles
4b First shielding particles
5, 5a Second metal particles
5b Second shielding particles
7a, 7b Welded part
8 First fixing tool
8a, 8b End portion
8c Flange
9 Adhesive layer
10, 20, 30, 40, 50, 60 Planar coil
11 Protective layer
11a Flange
12 Second fixing tool
12a Outer periphery
400 Semiconductor manufacturing device

1. A planar coil comprising:
a base comprising a first surface;
a metal layer located on the first surface and comprising a through hole and a plurality of voids; and
a first fixing tool inserted through the through hole and fixing the metal layer to the first surface side of the base.

2. The planar coil according to claim 1, wherein
the metal layer comprises a plurality of the through holes, and
a plurality of the first fixing tools inserted through the plurality of through holes, respectively, are provided.

3. The planar coil according to claim 1, wherein
the base comprises a recessed portion and one end portion of the first fixing tool is provided in the recessed portion.

4. The planar coil according to claim 3, wherein
an adhesive layer is provided in the recessed portion.

5. The planar coil according to claim 1, wherein
a protective layer is provided between the first fixing tool and the through hole.

6. The planar coil according to claim 5, wherein
the protective layer is an insulating material.

7. The planar coil according to claim 5, wherein the protective layer is resin.

8. The planar coil according to claim 7, wherein
a flange is provided on an end portion of the protective layer exposed from the metal layer.

9. The planar coil according to claim 1, wherein
a flange is provided on the other end portion of the first fixing tool.

10. The planar coil according to claim 9, wherein
a protective layer is provided between the first fixing tool and the through hole,
a second fixing tool is provided between the first fixing tool and the metal layer or the protective layer, and
an outer periphery of the second fixing tool is outside the flange of the first fixing tool.

11. The planar coil according to claim 10, wherein
the second fixing tool is an insulating material.

12. The planar coil according to claim 1, wherein
the metal layer is configured by layering a plurality of thin film coil conductors on the first surface in the thickness direction of the plurality of thin film coil conductors via a shielding layer to form a multilayer, and
the plurality of thin film coil conductors comprise voids.

13. The planar coil according to claim 12, wherein
the plurality of thin film coil conductors comprise first metal particles and second metal particles, and
the voids are located between the first metal particles and the second metal particles.

14. The planar coil according to claim 13, wherein
the plurality of thin film coil conductors further comprise third metal particles, and
the plurality of thin film coil conductors comprise welded parts between the first metal particles and the third metal particles.

15. The planar coil according to claim 12, wherein
each of the plurality of thin film coil conductors is thicker than the shielding layer.

16. The planar coil according to claim 12, wherein
the shielding layer comprises voids.

17. The planar coil according to claim 16, wherein
the shielding layer comprises first shielding particles and second shielding particles, and
the voids are located between the first shielding particles and the second shielding particles.

18. The planar coil according to claim 1, wherein
the first fixing tool is an insulating material and is a ceramic.

19. A semiconductor manufacturing device using the planar coil according to claim 1 as an antenna for high-frequency electrical power.
